(19) United States
(12) Patent Application Publication
(10) Pub. No.: US 2009/0091895 A1
(43) Pub. Date: Apr. 9, 2009

(54) ELECTRONIC CIRCUIT MODULE

(75) Inventor: Yoshikiyo WATANABE, Fukushima-ken (JP)

Correspondence Address: Beyer Law Group LLP, P.O. BOX 1687, Cupertino, CA, 95015-1687, US

(73) Assignee: ALPS ELECTRIC CO., LTD., Tokyo (JP)

(21) Appl. No.: 12/240,703

(22) Filed: Sep. 29, 2008

(30) Foreign Application Priority Data
Oct. 3, 2007 (JP) 2007-259972

(51) Int. Cl. H05K 1/02

(52) U.S. Cl. 361/743

(57) ABSTRACT

An electronic circuit module includes a circuit substrate whose two opposite side surfaces are provided with cutout portions; and a box-shaped cover body made of a metallic plate and having two claw segments individually disposed within the cutout portions, the cover body being attached to the circuit substrate so as to cover the top surface thereof. The circuit substrate has notches extending linearly inward beyond the opposite ends of each cutout portion from the corresponding side surface of the circuit substrate. The opposite ends of each claw segment in the width direction thereof are disposed facing linear sections of the corresponding notches within the corresponding cutout portion.

### CLAIM OF PRIORITY

This application claims benefit of the Japanese Patent Application No. 2007-259972 filed on Oct. 3, 2007, which is hereby incorporated by reference.

### BACKGROUND OF THE INVENTION

1. Field of the Invention

The present invention relates to an electronic circuit module formed by attaching a cover body made of a metallic plate to a circuit substrate, and particularly, to an electronic circuit module having a structure in which the cover body and the circuit substrate are positioned with respect to each other by disposing claw segments of the cover body within cutout portions provided in the side surfaces of the circuit substrate.

2. Description of the Related Art

With regard to wireless communication devices, for example, there are cases where these devices employ an electronic circuit module having a structure in which a cover body, such as a shield casing made of a metallic plate, is attached to a circuit substrate equipped with high-frequency circuits. Generally, in such an electronic circuit module, a box-shaped cover body is attached to the circuit substrate so as to cover the top surface thereof. With compact electronic circuit modules in particular, claw segments projecting from the sidewalls of the cover body are fitted to cutout portions provided respectively in two opposite side surfaces of the circuit substrate, and while maintaining this fitted state, the lower edges of the sidewalls of the cover body are soldered to a ground electrode formed on the top surface of the circuit substrate. See Japanese Unexamined Patent Application Publication No. 9-307261 for an example of this type of electronic circuit module.

FIG. 8 is a bottom view showing a related-art example of an electronic circuit module of this type. FIG. 9 illustrates a large board used for obtaining a plurality of circuit substrates to be included in the electronic circuit modules of the related art. As shown in FIG. 8, the electronic circuit module includes a rectangular circuit substrate 1, and the top surface of the circuit substrate 1 has, for example, high-frequency circuits (not shown) disposed thereon. Of the four side surfaces of the rectangular circuit substrate 1, the two opposite side surfaces at the longitudinal sides are respectively provided with positioning cutout portions 2 at the center of the side surfaces. A pair of claw segments 3a projecting downward from a cover body 3 that covers the top surface of the circuit substrate 1 are respectively fitted to these two cutout portions 2. The cutout portions 2 are formed in the following manner at the stage of a large board 1A shown in FIG. 9. Specifically, long holes 2A are formed astride opposite sides of vertical or horizontal cutting lines S₁, S₂ (e.g. the cutting lines S₂ in this case) extending on the large board 1A. The long holes 2A are then bisected along the corresponding cutting lines S₂ in a subsequent cutting process, thereby forming cutout portions 2. In a case where the circuit substrate 1 is a resin substrate of, for example, phenol resin, or more specifically a resin substrate composed of a rigid material, such as a halogen-free copper-clad laminate, the long holes 2A are formed as follows. First, a drill called a router is used to form a circular hole, and is then moved continuously along the corresponding cutting line S₂, thereby forming a long hole 2A.

The cover body 3 is made by forming a metallic plate into a box shape, and includes a rectangular top plate, sidewalls extending orthogonally from the four edges of the rectangular top plate, and the aforementioned claw segments 3a projecting from the center of the two opposite sidewalls at the longitudinal sides. In order to attach the cover body 3 to the circuit substrate 1, the two claw segments 3a are inserted into the corresponding cutout portions 2 from above the circuit substrate 1 until the sidewalls of the cover body 3 come into abutment with the top surface of the circuit substrate 1. In this manner, the height position of the cover body 3 can be set with respect to the circuit substrate 1, and the two claw segments 3a can be positionally controlled within the corresponding cutout portions 2, whereby displacement of the cover body 3 can be suppressed in the in-plane direction of the circuit substrate 1. After attaching the cover body 3 maintained in such positioned state to the circuit substrate 1 in this manner, the lower edges of the sidewalls are soldered onto a ground electrode (not shown) formed on the top surface of the circuit substrate 1, whereby the cover body 3 becomes electrically and mechanically connected to the circuit substrate 1. As a result, an electronic circuit module is formed.

As described above, in the electronic circuit module of the related art shown in FIG. 8, each of the cutout portions 2 in the circuit substrate 1 is made by first forming a circular hole in the large board 1A using a drill, then moving the drill linearly and continuously to form a long hole 2A, and finally bisecting the long hole 2A in the cutting process of the large board 1A. Therefore, the opposite longitudinal ends of the cutout portion 2 have a curved surface with the shape of a circular arc that corresponds to a quadrant of a circular hole. Although the claw segments 3a of the cover body 3 can be easily positioned in the thickness direction thereof within these cutout portions 2, the cutout portions 2 with this shape are problematic in that the claw segments 3a cannot be positioned accurately in the width direction thereof. In detail, as shown in FIG. 10 in a partially enlarged view, each claw segment 3a of the cover body 3 is disposed along a flat surface 2a extending in the longitudinal direction of the corresponding cutout portion 2. In this case, displacement of the cover body 3 can be suppressed in the Y direction (i.e. the thickness direction of the claw segment 3a) by bringing the inner surface of the claw segment 3a into abutment with this flat surface 2a. However, because the abutment of the inner surface of the claw segment 3a with the flat surface 2a can make it difficult to bring the opposite ends of the claw segment 3a in the width direction thereof into abutment with curved surfaces 2b of the cutout portion 2, relatively large clearances are required between the curved surfaces 2b and the claw segment 3a. In consequence, these clearances cause the cover body 3 to become loose in the X direction (i.e. the width direction of the claw segments 3a), thus making it difficult to set the attachment position of cover body 3 highly accurately with respect to the circuit substrate 1.

The same kind of cutout portions 2 may be formed in the other two side surfaces at the lateral sides of the circuit substrate 1. In that case, the four sidewalls of the cover body 3 may respectively have claw segments 3a projecting therefrom, so that these claw segments 3a can be fitted to the corresponding cutout portions 2. Although this configuration can allow the cover body 3 to be set in place highly accurately with respect to the circuit substrate 1 in both the X and Y directions, the cutout portions 2 increased to four sections in this manner can lead to many dead spaces created on the circuit substrate 1, thus unfavorably reducing the route flexibility for the wiring pattern and also making the cover body 3 into a complex shape. Especially in the case where the electronic circuit module is a type that has solder balls arranged on the undersurface of the circuit substrate 1 so as to be flip-chip mounted onto the top surface of a mother board, since the electronic circuit module requires a large number of solder balls on the undersurface of the circuit substrate 1, it is not desirable, in view of achieving compactness, to form the cutout portions 2 in the four side surfaces of the circuit substrate 1.

### SUMMARY OF THE INVENTION

The present invention provides an electronic circuit module in which the attachment position of a cover body can be set highly accurately with respect to a circuit substrate.

An electronic circuit module according to the present invention includes a rectangular circuit substrate whose two opposite side surfaces are provided with positioning cutout portions; and a box-shaped cover body made of a metallic plate and having a pair of claw segments individually disposed within the cutout portions, the cover body being attached to the circuit substrate so as to cover a top surface thereof. The circuit substrate has notches extending linearly inward beyond opposite ends of each cutout portion from the corresponding side surface of the circuit substrate. Furthermore, opposite ends of each claw segment in a width direction thereof are disposed facing linear sections of the corresponding notches within the corresponding cutout portion.

Accordingly, by disposing the claw segments of the cover body respectively within the cutout portions in the two opposite side surfaces of the circuit substrate, the cover body can be attached to the circuit substrate without play in both the thickness and width directions of the claw segments. Consequently, displacement of the cover body can be effectively suppressed in the in-plane direction of the circuit substrate.

In the above-described electronic circuit module, the cutout portions and the notches are preferably formed with a same drill. In this manner, the cutout portions having the notches can be formed with high accuracy, whereby the attachment position of the cover body can be set highly accurately with respect to the circuit substrate.

Furthermore, in the above-described electronic circuit module, it is preferable that an undersurface of the circuit substrate have arranged thereon a plurality of solder balls, and that the notches extend inward between outermost-arranged solder balls of the plurality of solder balls. In this manner, the tip end of each notch can be positioned as close as possible to the outermost solder balls, whereby an electronic circuit module of a flip-chip mounting type can be readily reduced in size.

### BRIEF DESCRIPTION OF THE DRAWINGS

FIG. 1 is an external view of an electronic circuit module according to an embodiment of the present invention;

FIG. 2 is a perspective view of a cover body included in the electronic circuit module as viewed from the underside thereof;

FIG. 3 is a perspective view of a circuit substrate included in the electronic circuit module as viewed from the upper side thereof;

FIG. 4 is an enlarged view of section IV in FIG. 3;

FIG. 5 illustrates a large board used for obtaining the circuit substrate in a plurality;

FIG. 6 is a perspective view of section VI in FIG. 1 as viewed from the underside; and

FIG. 7 is a bottom view that corresponds to FIG. 6;

FIG. 8 is a bottom view of an electronic circuit module of related art;

FIG. 9 illustrates a large board used for obtaining a plurality of circuit substrates to be included in the electronic circuit modules of the related art; and

FIG. 10 is an enlarged view of section C in FIG. 8.

### DESCRIPTION OF THE PREFERRED EMBODIMENT

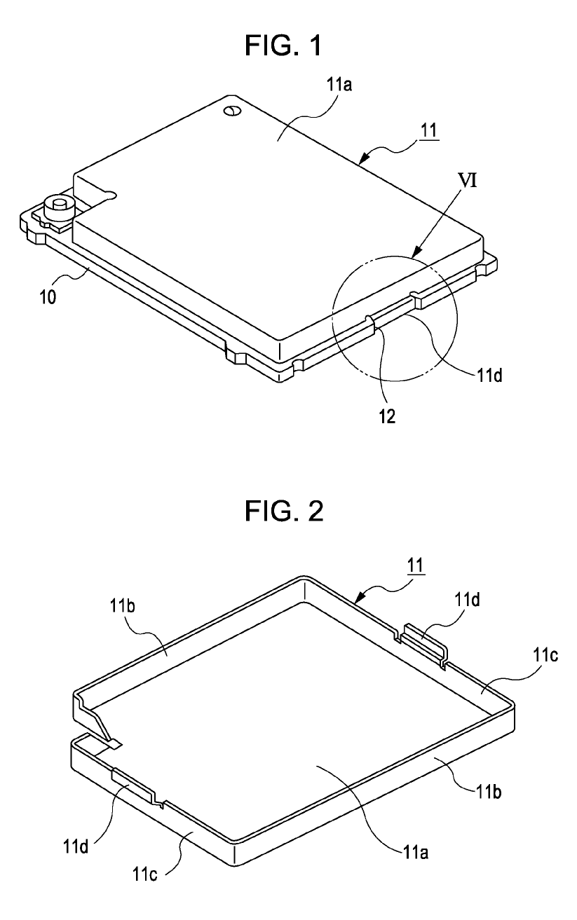

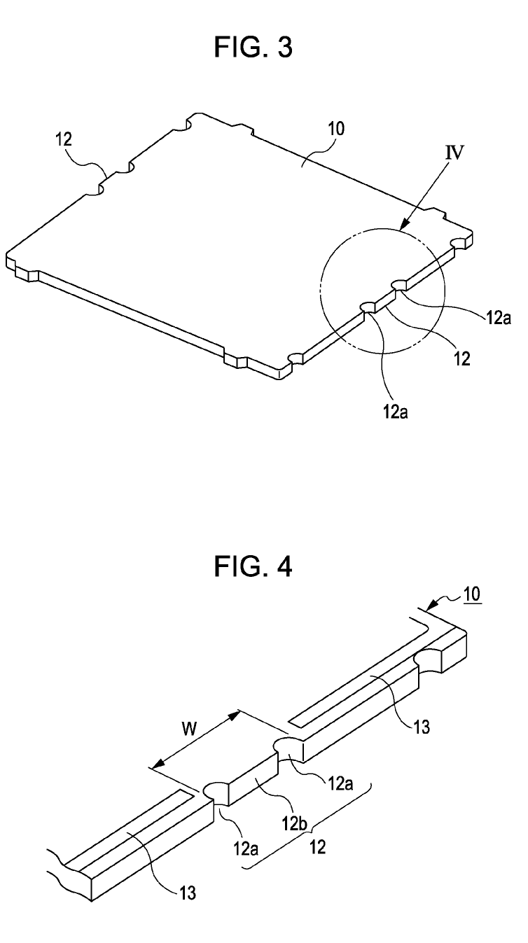

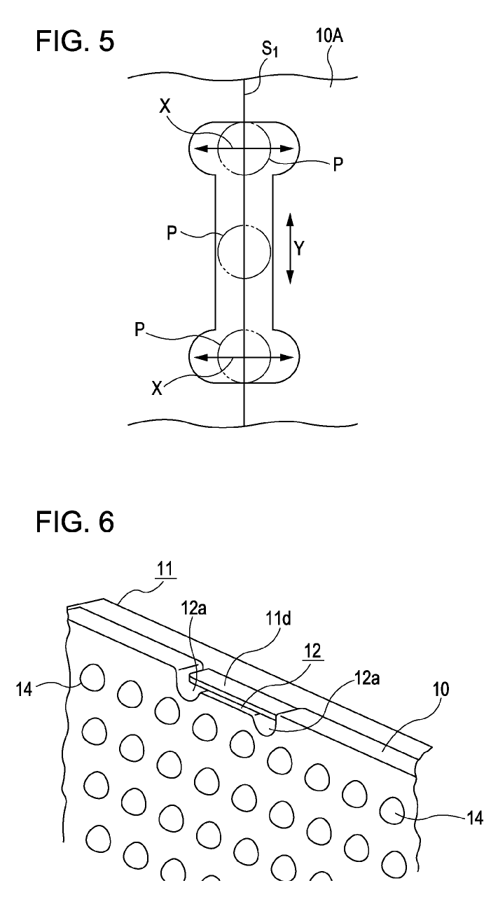

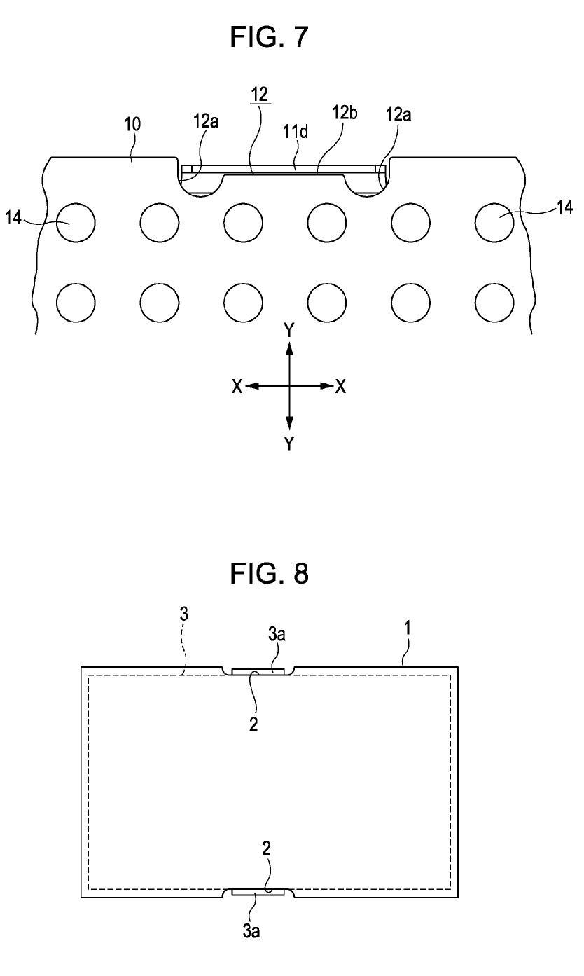

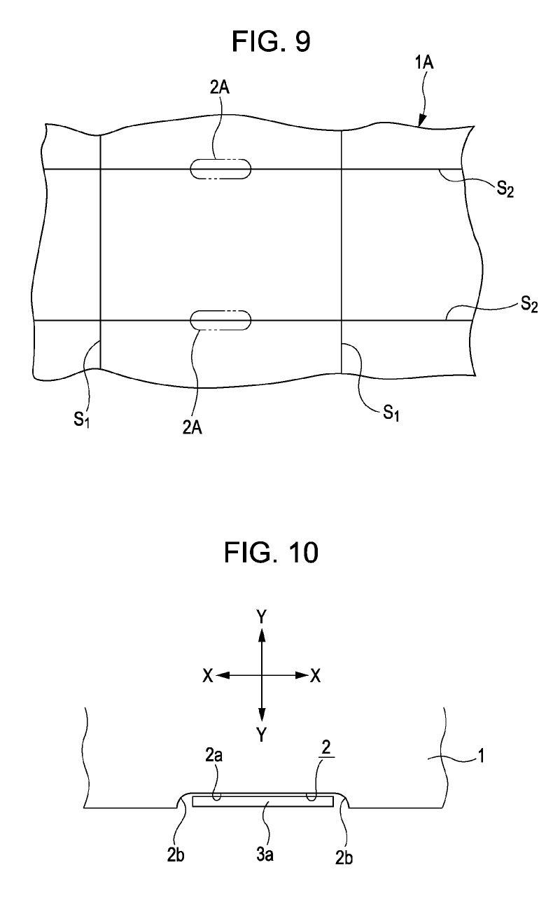

An embodiment of the present invention will be described below with reference to the drawings. FIG. 1 is an external view of an electronic circuit module according to the embodiment of the present invention. FIG. 2 is a perspective view of a cover body included in the electronic circuit module as viewed from the underside thereof. FIG. 3 is a perspective view of a circuit substrate included in the electronic circuit module as viewed from the upper side thereof. FIG. 4 is an enlarged view of section IV in FIG. 3. FIG. 5 illustrates a large board used for obtaining the circuit substrate in a plurality. FIG. 6 is a perspective view of section VI in FIG. 1 as viewed from the underside. FIG. 7 is a bottom view that corresponds to FIG. 6.

The electronic circuit module shown in FIG. 1 is formed by attaching a box-shaped cover body 11 made of a metallic plate onto a substantially rectangular circuit substrate 10 which is a resin substrate of, for example, phenol resin. The cover body 11 substantially covers the top surface of the circuit substrate 10. The circuit substrate 10 is composed of a halogen-free material not containing a bromine-based substance as a fire retardant. The two opposite side surfaces at the lateral sides of the substantially rectangular circuit substrate 10 are respectively provided with cutout portions 12 at the center of the side surfaces. As shown in FIGS. 3 and 4, each of these cutout portions 12 is a cutout formed along the corresponding side surface of the circuit substrate 10, and the longitudinal ends of the cutout portion 12 are respectively provided with notches 12a extending linearly inward from the side surface of the circuit substrate 10. Referring to FIG. 5, the cutout portions 12 having these notches 12a are formed in the following manner at the stage of a large board 10A used for obtaining the circuit substrate 10 in a plurality. Specifically, a circular hole P is formed on either a vertically or horizontally extending cutting line S₁ using a drill called a router, and this drill is moved continuously in the direction of an arrow Y extending along the cutting line S₁ and also in the direction of an arrow X extending orthogonally to the cutting line S₁, thereby forming an H-shaped long hole 12A. Subsequently, the long hole 12A is bisected in a cutting process of the large board 10A, thereby forming cutout portions 12 having notches 12a. As a result, each cutout portion 12 has a flat surface 12b extending parallel to the corresponding side surface of the circuit substrate 10 at a position inward of the side surface, and also has a pair of notches 12a extending linearly inward beyond the opposite ends of the flat surface 12b from the side surface of the circuit substrate 10.

Although not shown in the drawings, there are various kinds of electronic components mounted on the circuit substrate 10. These electronic components are connected to a wiring pattern so as to form a predetermined electronic circuit. Referring to FIG. 4, a ground electrode 13 is formed along the outer edges of the circuit substrate 10. The wiring pattern is connected to a land unit on the undersurface of the connector 10 via, for example, a through-hole conductor. On the other hand, referring to FIGS. 6 and 7, the undersurface of the circuit substrate 10 may be provided with a plurality of solder balls 14 attached to the land unit. The notches 12a in each of the cutout portions 12 described above may extend inward between outermost-arranged solder balls 14.

Referring to FIG. 2, the cover body 11 includes a rectangular top plate 11a, a pair of sidewalls 11b opposed to each other and extending orthogonally from the longitudinal edges of the rectangular top plate 11a, a pair of sidewalls 11c opposed to each other and extending orthogonally from the lateral edges of the rectangular top plate 11a, and two claw segments 11d projecting downward from the central sections of the two respective sidewalls 11c. These two claw segments 11d are provided at positions corresponding to the cutout portions 12 of the circuit substrate 10. Moreover, each claw segment 11d is given a width that is substantially equal to a width W (see FIG. 4) between the two notches 12a of the corresponding cutout portion 12.

In order to attach the cover body 11 to the circuit substrate 10, the two claw segments 11d are inserted into the corresponding cutout portions 12 from above the circuit substrate 10 until the lower edges of the sidewalls 11b and 11c come into abutment with the top surface of the circuit substrate 10. In this manner, the height position of the cover body 11 can be set accurately with respect to the circuit substrate 10, and the two claw segments 11d can be positioned in both the thickness and width directions thereof within the corresponding cutout portions 12. More specifically, the inner surface of each claw segment 11d is brought into abutment with the flat surface 12b of the corresponding cutout portion 12 so that the cover body 11 can be positioned in the Y direction in FIG. 7 (i.e. the thickness direction of the claw segment 11d), and moreover, the opposite ends of the claw segment 11d in the width direction thereof are brought into abutment with linear sections of the notches 12a so that the cover body 11 can be positioned in the X direction in FIG. 7 (i.e. the width direction of the claw segment 11d). Accordingly, the attachment position of the cover body 11 can be set accurately in the in-plane direction of the circuit substrate 10. After attaching the cover body 11 maintained in such positioned state to the circuit substrate 10 in this manner, the lower edges of the sidewalls 11b and 11c are soldered onto the ground electrode 13 on the circuit substrate 10, whereby the cover body 11 becomes electrically and mechanically connected to the circuit substrate 10. As a result, an electronic circuit module is formed.

As described above, the electronic circuit module according to this embodiment has a pair of notches 12a extending linearly inward beyond the opposite ends of each cutout portion 12 from the corresponding side surface of the circuit substrate 10, and the opposite ends of each claw segment 11d in the width direction thereof are disposed facing linear sections of the notches 12a within the corresponding cutout portion 12. Accordingly, by disposing the claw segments 11d of the cover body 11 respectively within the cutout portions 12 formed in the two opposite side surfaces of the circuit substrate 10, the cover body 11 can be attached to the circuit substrate 10 without play in both the thickness and width directions of the claw segments 11d. Consequently, displacement of the cover body 11 can be effectively suppressed in the in-plane direction of the circuit substrate 10 and the attachment position of the cover body 11 can be set highly accurately with respect to the circuit substrate 10 by simply forming the cutout portions 12 in the two opposite side surfaces of the circuit substrate 10. Furthermore, since the notches 12a formed at the opposite ends of each cutout portion 12 may extend inward between outermost-arranged solder balls 14 on the undersurface of the circuit substrate 10, the tip end of each notch 12a can be positioned as close as possible to the arrangement region of the solder balls 14. Accordingly, an electronic circuit module of a flip-chip mounting type suitable for compactness can be achieved.

Although the above embodiment is directed to a case where the circuit substrate 10 used is a resin substrate, the present invention is applicable to a case where the circuit substrate 10 is a ceramic substrate.

What is claimed is:

1. An electronic circuit module comprising:
a rectangular circuit substrate whose two opposite side surfaces are provided with positioning cutout portions; and
a box-shaped cover body made of a metallic plate and having a pair of claw segments individually disposed within the cutout portions, the cover body being attached to the circuit substrate so as to cover a top surface thereof,
wherein the circuit substrate has notches extending linearly inward beyond opposite ends of each cutout portion from the corresponding side surface of the circuit substrate, and wherein opposite ends of each claw segment in a width direction thereof are disposed facing linear sections of the corresponding notches within the corresponding cutout portion.

2. The electronic circuit module according to claim 1, wherein the cutout portions and the notches are formed with a same drill.

3. The electronic circuit module according to claim 1, wherein an undersurface of the circuit substrate has arranged thereon a plurality of solder balls, and wherein the notches extend inward between outermost-arranged solder balls of the plurality of solder balls.
